(19) United States
(12) Patent Application Publication
(10) Pub. No.: US 2019/0180924 A1
(43) Pub. Date: Jun. 13, 2019

(54) COIL MODULE, FILTER MODULE AND POWER MODULE

(71) Applicant: PEGATRON CORPORATION, Taipei City (TW)

(72) Inventor: Feng-Lang LEE, TAIPEI CITY (TW)

(21) Appl. No.: 16/178,578

(22) Filed: Nov. 1, 2018

(30) Foreign Application Priority Data
Dec. 12, 2017 (TW) 106143601

(51) Int. Cl. H01F 27/28; H03H 7/01; H02M 1/12

(52) U.S. Cl. CPC H01F 27/2895; H03H 7/1758; H02M 2001/0064; H02M 1/126; H02M 2001/123; H03H 7/0123

(57) ABSTRACT

The present application provides a coil module, a filter module and a power module. The coil module comprises a ring core, a first coil and a second coil, the first coil and the second coil are wound around both sides of the ring core in a symmetrical manner, and the first coil and the second coil are disconnected from each other.

### REFERENCE TO RELATED APPLICATION

This application claims priority benefit of Taiwan Application Serial Number 106143601, filed Dec. 12, 2017. The entirety of the above-mentioned patent application is hereby incorporated by reference herein and made a part of specification.

### BACKGROUND

### Technical Field

The present application relates to a device. More particularly, the present application relates to a coil module, a filter module, and a power module.

### Related Art

The voltage generated by the AC/DC power circuit is equivalent to the voltage ripples or is equivalent to a rapid voltage change of the system terminals. The interference may be coupled into other circuits due to the stray capacitance, thereby causing the common mode problems. In the prior art, the small LC filter is used to remove noise. As shown in FIG. 1, the small LC filter is composed of a normal inductor L and a normal capacitor C.

In the related art, the small LC filters are not effective to suppress the conducted interference, thereby causing the serious interference between the RF circuit and other circuits. It is important to effectively suppress the conducted interference between the communication devices and ICs of various applications.

### SUMMARY

The present application discloses a coil module, a filter module, and a power module.

In one embodiment of the application, a coil module comprises a ring core, a first coil and a second coil. The first coil and the second coil are wound around both sides of the ring core in a symmetrical manner. The first coil and the second coil are disconnected from each other.

In another embodiment of the application, a filter module comprises a capacitor, a first coil module, and a second coil module. The first coil module and the second coil module are connected to two ends of the capacitor in a symmetrical manner.

In one embodiment of the application, a power module comprises an AC power input module, a switching mode high frequency DC power module, a filter module, and a DC output module. The switching mode high frequency DC power module is electrically connected to the AC power input module. The filter module comprising a capacitor, a first coil module, and a second coil module. The first coil module and the second coil module are electrically connected to two ends of the capacitor. The first coil module is electrically connected to the switching mode high frequency DC power module. The DC output module is electrically connected to the second coil module of the filter module. The DC output module outputs DC power to a system terminal module.

To sum up, the technical solution of the present application has apparent advantages and beneficial effects in comparison with the prior art. By the technical solution of the present application, the noise transmitting by the DC power can effectively prevent.

The foregoing description is described in detail below with reference to the implementation manners, and the technical solutions of the present application are further explained.

### BRIEF DESCRIPTION OF THE DRAWINGS

In order to let above mention of the present application and other objects, features, advantages, and embodiments of the present application to be more easily understood, the description of the accompanying drawing as follows:

FIG. 1 illustrates a circuit diagram of a small LC filter in prior art.

FIG. 2A illustrates a front view of a coil module according to one embodiment of the present application.

FIG. 2B illustrates a side view of the coil module according to one embodiment of the present application.

FIG. 3 illustrates a perspective view of a coil module according to another embodiment of the present application.

FIG. 4 illustrates a side view of a filter module according to one embodiment of the present application.

FIG. 5 illustrates a block diagram of a power module according to one embodiment of the present application.

FIG. 6 illustrates a noise spectrum diagram of a power module using the small LC filter in FIG. 1.

FIG. 7 illustrates a noise spectrum diagram of the power module in FIG. 5.

### DETAILED DESCRIPTION OF THE EMBODIMENTS

Reference may be made to the accompanying drawings and various embodiments described below in order to make the application more complete and detailed. The same symbols among the different drawing indicate the same or similar elements. On the other hand, known components and steps are not described in detail in the embodiments to avoid unnecessary limitation of the application.

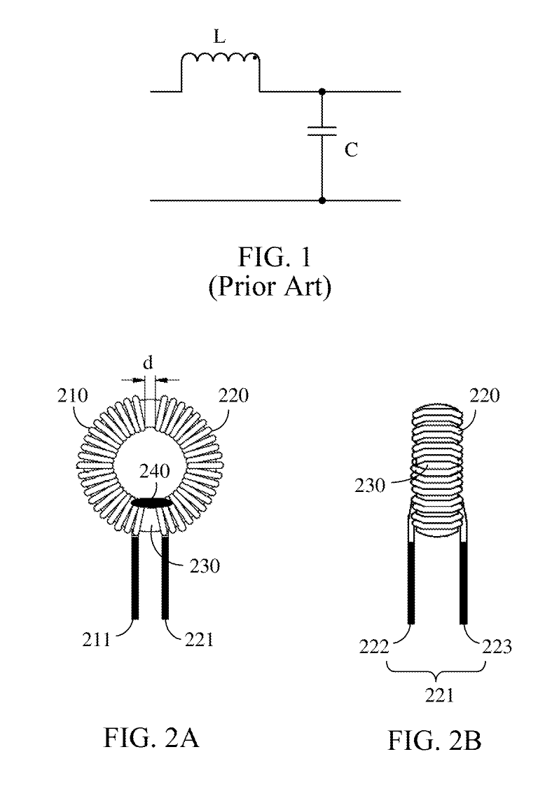

FIG. 2A illustrates a front view of a coil module according to one embodiment of the present application. As shown in FIG. 2A, the coil module includes a first coil 210, a second coil 220, and a ring core 230. In structure, the first coil 210 and the second coil 220 are wound around both sides of the ring core 230 in a symmetrical manner. The first coil 210 and the second coil 220 are disconnected from each other. It should be understood that the first coil 210 and the second coil 220 are wound around the same ring core 230 instead of being wound around different winding slots, thereby reducing the stray capacitance and reducing the volume.

In practice, the first coil 210 and the second coil 220 are both conducting wires. The number of turns of the first coil 210 is the same as the number of turns of the second coil 220, such as 10 to 20 turns, thereby effectively suppressing the low frequency noise. The first coil 210 and the second coil 220 are spaced apart by a predetermined distance d, thereby forming two inductors. The predetermined distance d may be 5 to 10 mm. The coil module further includes a fixed member 240. The fixed member 240 is attached to the first coil 210, the second coil 220, and the inner edge of the ring core 230 between the first coil 210 and the second coil 220, so that the positions of the first coil 210 and the second coil 220 on the ring core 230 are fixed. In one embodiment, the fixed member 240 may be epoxy or other suitable material.

An end 211 of the first coil 210 and an end 221 of the second coil 221 may extent to connect a circuit board, such as the circuit board 401 shown in FIG. 4.

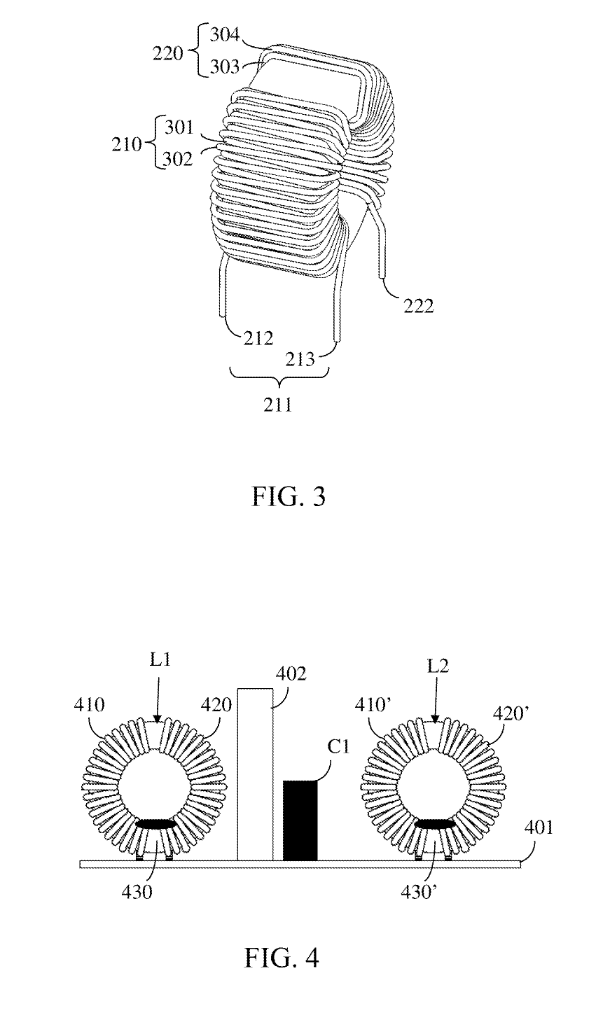

FIG. 2B illustrates a side view of the coil module according to one embodiment of the present application. As shown in FIG. 2B, the end 221 of the second coil 220 has two terminal 222 and 223 to electrically connect to different circuit components (such as the capacitors and the DC modules), respectively. Since the second coil 220 is symmetrical to the first coil 210, the end 211 of the first coil 210 also has two terminals 212 and 213, as shown in FIG. 3.

FIG. 3 illustrates a perspective view of a coil module according to another embodiment of the present application. The coil module of FIG. 3 is substantially identical to the coil module of FIGS. 2A and 2B except that the structure of the coil module of FIG. 3 is that the returned winding should be crossed to the gap. Specifically, the first coil 210 includes a first partial winding 301 and a second partial winding 302 connected to each other. The first partial winding 301 forms a layer of winding wound around a periphery of one side of the ring core 230, and the second partial winding 302 is returned back and interleaved with the first partial winding 301 to fill the gap on the side of the ring core 230 which is not wound by the first partial winding 301, thereby increasing the inductance. Similarly, the second coil 220 includes a third partial winding 303 and a fourth partial winding 304 connected to each other. The third partial winding 303 forms a layer of winding wound around a periphery of the other side of the ring core 230, and the fourth partial winding 304 is returned back and interleaved with the third partial winding 303, thereby increasing the inductance.

FIG. 4 illustrates a side view of a filter module according to one embodiment of the present application. As shown in FIG. 4, the filter module includes a capacitor C1, a first coil module L1, and a second coil module L2. In structure, the first coil module L1 and the second coil module L2 are connected to two ends of the capacitor C1 in a symmetrical manner.

The first coil module L1 includes a first coil 410, a second coil 420, and a first ring core 430. The first coil 410 and the second coil 420 are wound around both sides of the first ring core 430 in a symmetrical manner. The first coil 410 and the second coil 420 are disconnected from each other. In one embodiment, the structure of the first coil 410, the second coil 420, and the first ring core 430 is substantially identical to the abovementioned structure of the first coil 210, the second coil 220, and the ring core 230, and is not repeated here.

The second coil module L2 includes a third coil 410′, a fourth coil 420′, and a second ring core 430′. The third coil 410′ and the fourth coil 420′ are wound around both sides of the second ring core 430′ in a symmetrical manner. The third coil 410′ and the fourth coil 420′ are disconnected from each other. In one embodiment, the structure of the third coil 410′, the fourth coil 420′, and the second ring core 430′ is substantially identical to the abovementioned structure of the first coil 210, the second coil 220, and the ring core 230, and is not repeated here.

As shown in FIG. 4, the filter module further includes a circuit board 401 and a block piece 402. The capacitor C1, the first coil module L1, and the second coil module L2 are disposed on the circuit board 401. The block piece 402 is erected on the circuit board 402. A height of the block piece 402 is greater than a height of any one of the capacitor C1, the first coil module L1, and the second coil module L2, thereby preventing the cover or other components to be pressed the first coil module L1 or the second coil module L2. In one embodiment, the block piece 402 may be a rigid plastic tube or other suitable components.

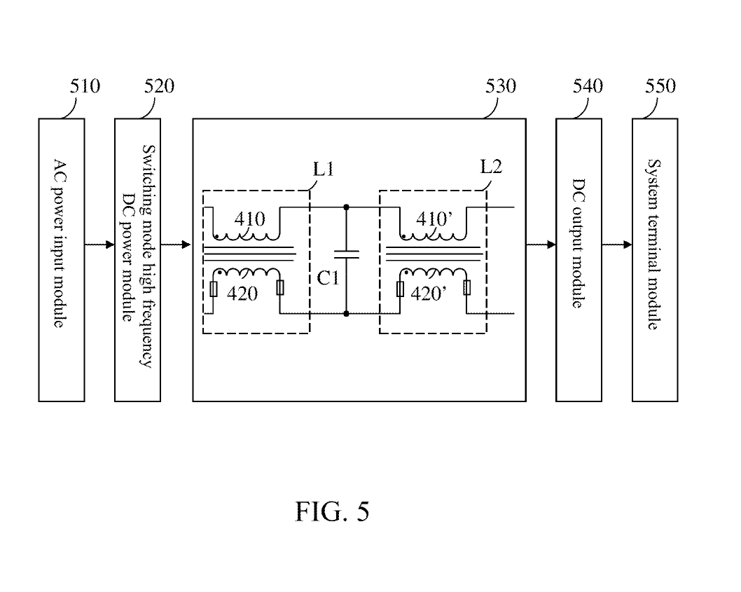

FIG. 5 illustrates a block diagram of a power module according to one embodiment of the present application. As shown in FIG. 5, the power module includes an AC power input module 510, a switching mode high frequency DC power module 520, a filter module 530, and a DC output module 540.

In structure, the switching mode high frequency DC power module 520 is electrically connected to the AC power input module 510. The filter module 530 includes a capacitor C1, a first coil module L1, and a second coil module L2. The first coil module L1 and the second coil module L2 are connected to two ends of the capacitor C1. The first coil module L1 is electrically connected to the switching mode high frequency DC power module 520. The DC output module 540 is electrically connected to the second coil module L2 of the filter module 530. The DC output module 540 outputs DC power to a system terminal module 550.

In practice, the AC power input module 510 may be a universal input port, and the switching mode high frequency DC power module 520 may be a full-bridge AC/DC converter circuit, and the DC output module 540 may be a DC/DC converter circuit, and the system terminal module 550 may be a wireless system terminal module (such as a RF circuit, a WiFI module, etc.).

The capacitor C1 may be an electrolytic capacitor. The electric material of the electrolytic capacitor is a dense oxide film formed by the surface of the anode metal material. The cathode material of the electrolytic capacitor is an electrolyte. At the same volume, the electrolytic capacitor may obtain much larger capacitance than the normal capacitor.

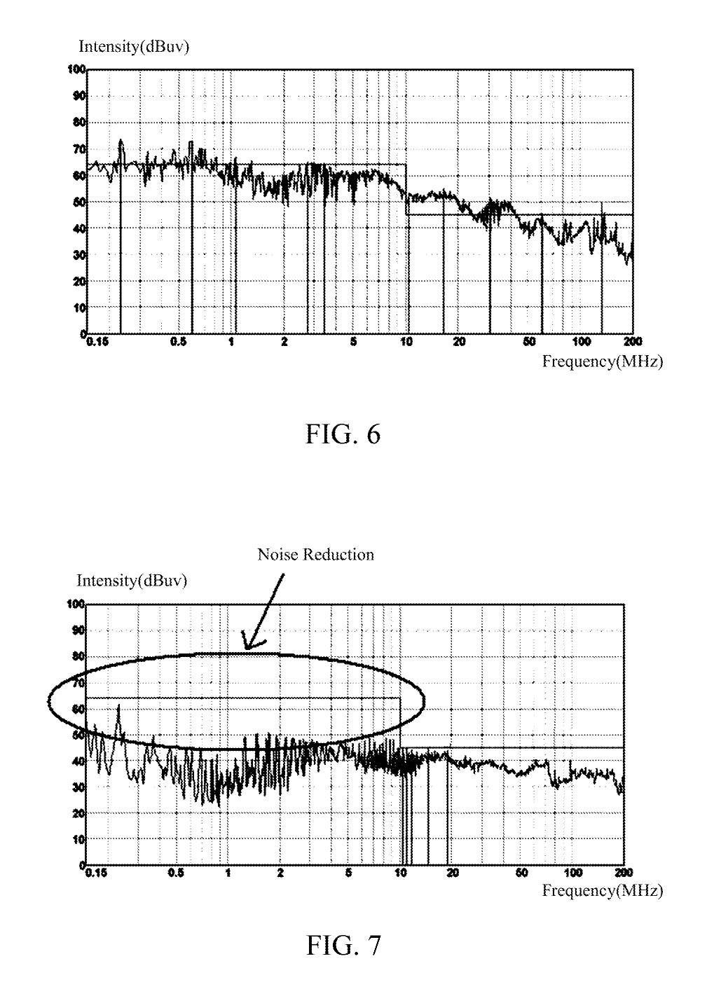

In a comparative example, if the filter module 530 of the power module is replaced by the small LC filter, the noise spectrum diagram of the power module is shown in FIG. 6, and the noise of the low frequency region (about 0.15 to 10 MHz) is very high.

In present embodiment, the noise spectrum diagram of the power module using the filter module 530 is shown in FIG. 7. Compared with FIG. 6, the noise of the low frequency region (about 0.15 to 10 MHz) is significant reduced. Therefore, the filter module 530 may effectively suppress the conducted interference transmitting to the system terminal module 550 (such as RF circuit) and serious interference causing between the system terminal module 550 and several different DC circuits (i.e., the switching mode high frequency DC power module 520 and the DC output module 540).

To sum up, the technical solution of the present application has apparent advantages and beneficial effects in comparison with the prior art. By the technical solution of the present application, the noise transmitting by the DC power can effectively prevent.

Although above DETAILED DESCRIPTION discloses the specific embodiment of the present application. However, it is not used to limit the present application. Those skilled in the art can make various changes and modifications of the present application without departing from the principle and spirit of the present application. Therefore, the scope of the present application should refer to the following claims.

What is claimed is:

1. A coil module, comprising:
a ring core; and
a first coil and a second coil wound around both sides of the ring core in a symmetrical manner, wherein the first coil and the second coil are disconnected from each other.

2. The coil module of claim 1, wherein a number of turns of the first coil is the same as a number of turns of the second coil.

3. The coil module of claim 1, wherein the first coil and the second coil are spaced apart by a predetermined distance.

4. The coil module of claim 1,
wherein the first coil comprises a first partial winding and a second partial winding connected to each other, wherein the first partial winding is wound around a periphery of one of the both sides of the ring core, and the second partial winding is returned back and interleaved with the first partial winding,
wherein the second coil comprises a third partial winding and a fourth partial winding connected to each other, wherein the third partial winding is wound around a periphery of the other one of the both sides of the ring core, and the fourth partial winding is returned back and interleaved with the third partial winding.

5. A filter module, comprising:
a capacitor; and
a first coil module and a second coil module connected to two ends of the capacitor in a symmetrical manner.

6. The filter module of claim 5, wherein the first coil module comprises:
a first ring core; and
a first coil and a second coil wound around both sides of the first ring core in the symmetrical manner, wherein the first coil and the second coil are disconnected from each other.

7. The filter module of claim 6,
wherein the first coil comprises a first partial winding and a second partial winding connected to each other, wherein the first partial winding of the first coil is wound around a periphery of one of the both sides of the first ring core, and the second partial winding of the first coil is returned back and interleaved with the first partial winding of the first coil,
wherein the second coil comprises a third partial winding and a fourth partial winding connected to each other, wherein the third partial winding of the second coil is wound around a periphery of the other one of the both sides of the first ring core, and the fourth partial winding of the second coil is returned back and interleaved with the third partial winding of the second coil.

8. The filter module of claim 5, wherein the second coil module comprises:
a second ring core; and
a third coil and a fourth coil wound around both sides of the second ring core in a symmetrical manner, wherein the third coil and the fourth coil are disconnected from each other.

9. The filter module of claim 8,
wherein the third coil comprises a first partial winding and a second partial winding connected to each other, wherein the first partial winding of the third coil is wound around a periphery of one of the both sides of the second ring core, and the second partial winding of the third coil is returned back and interleaved with the first partial winding of the third coil,
wherein the fourth coil comprises a third partial winding and a fourth partial winding connected to each other, wherein the third partial winding of the fourth coil is wound around a periphery of the other one of the both sides of the second ring core, and the fourth partial winding of the fourth coil is returned back and interleaved with the third partial winding of the fourth coil.

10. The filter module of claim 6, further comprising:
a circuit board, wherein the capacitor, the first coil module, and the second coil module are disposed on the circuit board; and
a block piece erected on the circuit board, wherein a height of the block piece is greater than a height of any one of the capacitor, the first coil module, and the second coil module.

11. A power module, comprising:
an AC power input module;
a switching mode high frequency DC power module electrically connected to the AC power input module;
a filter module comprising a capacitor, a first coil module, and a second coil module, wherein the first coil module and the second coil module are connected to two ends of the capacitor, wherein the first coil module is electrically connected to the switching mode high frequency DC power module; and
a DC output module electrically connected to the second coil module of the filter module, wherein the DC output module outputs DC power to a system terminal module.

12. The power module of claim 11, wherein the first coil module comprises:
a first ring core; and
a first coil and a second coil wound around both sides of the first ring core in a symmetrical manner, wherein the first coil and the second coil are disconnected from each other.

13. The power module of claim 12,
wherein the first coil comprises a first partial winding and a second partial winding connected to each other, wherein the first partial winding of the first coil is wound around a periphery of one of the both sides of the first ring core, and the second partial winding of the first coil is returned back and interleaved with the first partial winding of the first coil,
wherein the second coil comprises a third partial winding and a fourth partial winding connected to each other, wherein the third partial winding of the second coil is wound around a periphery of the other one of the both sides of the first ring core, and the fourth partial winding of the second coil is returned back and interleaved with the third partial winding of the second coil.

14. The power module of claim 11, wherein the second coil module comprises:
a second ring core; and
a third coil and a fourth coil wound around both sides of the second ring core in a symmetrical manner, wherein the third coil and the fourth coil are disconnected from each other.

15. The power module of claim 14,
wherein the third coil comprises a first partial winding and a second partial winding connected to each other, wherein the first partial winding of the third coil is wound around a periphery of one of the both sides of the second ring core, and the second partial winding of the third coil is returned back and interleaved with the first partial winding of the third coil,
wherein the fourth coil comprises a third partial winding and a fourth partial winding connected to each other, wherein the third partial winding of the fourth coil is wound around a periphery of the other one of the both sides of the second ring core, and the fourth partial winding of the fourth coil is returned back and interleaved with the third partial winding of the fourth coil.
